(19) United States
(12) Patent Application Publication
(10) Pub. No.: US 2025/0377426 A1
(43) Pub. Date: Dec. 11, 2025

(54) MAGNETIC RESONANCE IMAGING APPARATUS

(71) Applicant: FUJIFILM Corporation, Tokyo (JP)

(72) Inventors: Takashi CHUMAN, Tokyo (JP); Atsushi OTA, Tokyo (JP); Koki ISHII, Tokyo (JP)

(73) Assignee: FUJIFILM Corporation, Tokyo (JP)

(21) Appl. No.: 19/230,981

(22) Filed: Jun. 6, 2025

(30) Foreign Application Priority Data
Jun. 7, 2024 (JP) 2024-092779

(51) Int. Cl. G01R 33/36; G01R 33/34

(52) U.S. Cl. CPC G01R 33/3692; G01R 33/34007; G01R 33/3621

(57) ABSTRACT

A magnetic resonance imaging apparatus according to one aspect of the present invention includes: a top plate on which a subject is placed, the top plate being slidable in a longitudinal direction; a first wireless transceiver connected to a receive coil for capturing a magnetic resonance image of the subject; a moving mechanism that moves the first wireless transceiver in a direction away from an end part of the top plate in the longitudinal direction; a second wireless transceiver; and a controller that controls movement of the first wireless transceiver via the moving mechanism and wireless communication using the first wireless transceiver and the second wireless transceiver, in which the controller determines a movement amount of the first wireless transceiver via the moving mechanism and performs the wireless communication by moving the first wireless transceiver by the determined movement amount via the moving mechanism.

### CROSS-REFERENCE TO RELATED APPLICATION

The present application claims priority under 35 U.S.C § 119 (a) to Japanese Patent Application No. 2024-092779 filed on Jun. 7, 2024, which is hereby expressly incorporated by reference, in its entirety, into the present application.

### BACKGROUND OF THE INVENTION

### 1. Field of the Invention

The present invention relates to a magnetic resonance imaging apparatus, and particularly to a technique of capturing a magnetic resonance image using wireless communication.

### 2. Description of the Related Art

A physical cable connected to a radio frequency (RF) coil of a magnetic resonance imaging (MRI) apparatus may hinder a setting operation of a user, and also lead to an increase in cable diameter and cost as the number of channels of a receive coil increases. In response to such a situation, a technique of performing wireless communication between the RF coil and a control unit has been developed. For example, US2022/0265496A and JP2021-101852A disclose that wireless communication is performed using a wireless transceiver provided on an end part of a top plate.

### SUMMARY OF THE INVENTION

In recent years, with an increase in the total number of channels of the MRI apparatus, the number of signal lines transmitted to a control unit of a machine room through an inside of a bed and a filter box tends to increase. Therefore, it is desired to reduce the number of signal lines through digitization or optical conversion, but analog/digital (AD) conversion and electrical signal/optical signal (EO; conversion from electrical signal to optical signal) conversion in the vicinity of the RF coil are easily affected by a static magnetic field, radio frequency irradiation, a gradient magnetic field (hereinafter, referred to as “static magnetic field or the like”), or the like.

Therefore, it is preferable to perform wireless communication so as not to be affected by a static magnetic field or the like; however, depending on an imaging part of a subject, a body position on a top plate (whether a head or a leg is placed on a main body side), and the like, the wireless transceiver may be located in an imaging space or in the vicinity of the imaging space. However, in the above-described techniques disclosed in US2022/0265496A and JP2021-101852A, the wireless transceiver is fixed to the top plate, so that it is difficult to reduce or avoid an influence of a static magnetic field or the like on wireless communication, which may cause a deterioration in quality of the wireless communication and a deterioration in quality of a magnetic resonance image.

As described above, the techniques in the related art have not been capable of capturing a magnetic resonance image through high-quality wireless communication.

The present invention has been made in view of such circumstances, and an object of the present invention is to provide a magnetic resonance imaging apparatus capable of capturing a magnetic resonance image through high-quality wireless communication.

In order to achieve the above-described object, a magnetic resonance imaging apparatus according to a first aspect of the present invention comprises: a top plate on which a subject is placed, the top plate being slidable in a longitudinal direction; a first wireless transceiver connected to a receive coil for capturing a magnetic resonance image of the subject; a moving mechanism that moves the first wireless transceiver in a direction away from an end part of the top plate in the longitudinal direction; a second wireless transceiver; and a controller that controls movement of the first wireless transceiver via the moving mechanism and wireless communication using the first wireless transceiver and the second wireless transceiver, in which the controller determines a movement amount of the first wireless transceiver via the moving mechanism and performs the wireless communication by moving the first wireless transceiver by the determined movement amount via the moving mechanism.

According to the first aspect, since the first wireless transceiver is moved in the direction away from the end part of the top plate in the longitudinal direction, it is possible to reduce or avoid an influence of a static magnetic field or the like on the wireless communication by moving the first wireless transceiver as necessary, and thus it is possible to capture the magnetic resonance image by performing the high-quality wireless communication.

A second aspect provides the magnetic resonance imaging apparatus according to the first aspect, in which the controller determines the movement amount in consideration of one or more of an imaging part of the subject, a direction of placing the subject on the top plate, and a size of an imaging space of the magnetic resonance imaging apparatus. In the second aspect, a method of determining the movement amount is specifically defined.

A third aspect provides the magnetic resonance imaging apparatus according to the first to second aspect, in which the controller determines a movement amount for positioning the first wireless transceiver outside an imaging space of the magnetic resonance imaging apparatus, as the movement amount. In the third aspect, another example of the criterion for determining the movement amount is defined.

A fourth aspect provides the magnetic resonance imaging apparatus according to any one of the first to third aspects, in which the controller determines the movement amount in consideration of quality of the wireless communication. In the fourth aspect, an example of the criterion for determining the movement amount is defined.

A fifth aspect provides the magnetic resonance imaging apparatus according to any one of the first to fourth aspects, in which the controller obtains quality of the wireless communication through preliminary measurement before main imaging. In the fifth aspect, another example of the criterion for determining the movement amount is defined.

A sixth aspect provides the magnetic resonance imaging apparatus according to any one of the first to fifth aspects, in which the controller measures quality of the wireless communication after the first wireless transceiver is moved, determines the movement amount again according to a result of the measurement, and moves the first wireless transceiver by the movement amount determined again. In the sixth aspect, it is specified that the determination of the movement amount and the movement may be repeated.

A seventh aspect provides the magnetic resonance imaging apparatus according to any one of the first to sixth aspects, which further comprises: a locking mechanism that locks and unlocks movement of the first wireless transceiver via the moving mechanism, in which the controller unlocks the moving mechanism via the locking mechanism during the movement, and locks the moving mechanism via the locking mechanism after the movement is ended. As in the seventh aspect, by locking the moving mechanism and thereby fixing the position of the wireless transceiver, it is possible to maintain the quality of the wireless communication and improve safety during the use of the apparatus.

An eighth aspect provides the magnetic resonance imaging apparatus according to any one of the first to seventh aspects, in which the moving mechanisms are provided at both end parts of the top plate in the longitudinal direction, and the first wireless transceivers are provided corresponding to the moving mechanisms at both end parts of the top plate. In the eighth aspect, a specific aspect of the disposition of the moving mechanism and the wireless transceiver is defined.

A ninth aspect provides the magnetic resonance imaging apparatus according to the eighth aspect, in which the controller selects the first wireless transceiver provided at either one of both end parts of the top plate, and performs the wireless communication using the selected first wireless transceiver. According to the ninth aspect, it is possible to perform the wireless communication by selecting an appropriate wireless transceiver.

A tenth aspect provides the magnetic resonance imaging apparatus according to any one of the first to ninth aspects, in which the moving mechanism moves the first wireless transceiver in multiple stages or continuously. According to the tenth aspect, the movement can be performed with an optimal movement amount.

An eleventh aspect provides the magnetic resonance imaging apparatus according to any one of the first to tenth aspects, in which the controller causes an output device to output information indicating the movement amount and/or a position of the first wireless transceiver corresponding to the movement amount. According to the eleventh aspect, a user can know the movement amount and/or the position of the wireless transceiver. The output may be performed by a display on a display device or may be performed by a voice output by a voice output device.

A twelfth aspect provides the magnetic resonance imaging apparatus according to any one of the first to eleventh aspects, in which the controller causes an output device to output information indicating quality of the wireless communication in a state in which the moving mechanism moves the first wireless transceiver. According to the twelfth aspect, the user can know the quality of the wireless communication. The output may be performed by a display on a display device or may be performed by a voice output by a voice output device.

A thirteenth aspect provides the magnetic resonance imaging apparatus according to any one of the first to twelfth aspects, in which the moving mechanism is an extension mechanism provided on the top plate, and the controller extends the extension mechanism to move the first wireless transceiver in the direction away from the end part of the top plate in a case of imaging the subject. In the thirteenth aspect, an example of a configuration of the moving mechanism is defined.

A fourteenth aspect provides the magnetic resonance imaging apparatus according to any one of the first to thirteenth aspects, in which the moving mechanism includes an arm member provided on the top plate, one end part of the arm member serving as a rotary shaft, the first wireless transceiver is provided at the other end part of the arm member, and the controller moves the first wireless transceiver in the direction away from the end part of the top plate by rotating the arm member. In the fourteenth aspect, another example of the configuration of the moving mechanism is defined.

A fifteenth aspect provides the magnetic resonance imaging apparatus according to any one of the first to fourteenth aspects, in which the first wireless transceiver and the receive coil are connected by wireless communication. According to the fifteenth aspect, it is possible to reduce the number of cables.

A sixteenth aspect provides the magnetic resonance imaging apparatus according to any one of the first to fourteenth aspects, in which the wireless communication is wireless communication using light. In the sixteenth aspect, an example of a method of the wireless communication is defined.

As described above, with the magnetic resonance imaging apparatus of the aspect of the present invention, it is possible to capture a magnetic resonance image through high-quality wireless communication.

### BRIEF DESCRIPTION OF THE DRAWINGS

FIG. 1 is a diagram showing an overall configuration of a magnetic resonance imaging apparatus according to a first embodiment.

FIG. 2 is a diagram showing an installation example of a wireless transceiver in the first embodiment.

FIGS. 3A and 3B are diagrams showing an installation example of a wireless transceiver and an extension mechanism.

FIGS. 4A to 4C are diagrams showing a disposition example of a filter box and a wireless transceiver.

FIG. 5 is a schematic diagram showing a configuration example of the extension mechanism.

FIGS. 6A and 6B are schematic diagrams showing a configuration example of a locking mechanism.

FIGS. 7A to 7C are diagrams showing a state of locking/unlocking of the extension mechanism via the locking mechanism.

FIG. 8 is a diagram showing a state of wireless communication in the first embodiment.

FIG. 9 is a diagram showing a configuration of a control device.

FIG. 10 is a flowchart showing processing of moving the wireless transceiver through extension of the extension mechanism.

FIGS. 11A to 11D are diagrams showing an example of quality display of wireless communication.

FIGS. 12A to 12C are diagrams showing another example of quality display of wireless communication.

FIGS. 13A to 13F are diagrams showing an aspect of imaging in consideration of an imaging part and a body position.

FIGS. 14A to 14F are diagrams showing a modification example of disposition of the extension mechanism and the wireless transceiver.

FIG. 15 is a schematic diagram showing a modification example (part 1) of the extension mechanism.

FIGS. 16A and 16B are schematic diagrams showing a modification example (part 2) of the extension mechanism.

FIGS. 17A and 17B are schematic diagrams showing a modification example of a moving mechanism.

FIG. 18 is a diagram showing a main configuration of a magnetic resonance imaging apparatus according to a second embodiment.

FIG. 19 is a diagram showing an installation example of a wireless transceiver in the second embodiment.

FIG. 20 is a diagram showing a state of wireless communication in the second embodiment.

FIG. 21 is a flowchart showing processing in a case in which wireless communication is disconnected or quality of the wireless communication is deteriorated.

FIG. 22 is a diagram showing a main configuration of a magnetic resonance imaging apparatus according to a third embodiment.

FIG. 23 is a diagram showing a state of wireless communication in the third embodiment.

### DESCRIPTION OF THE PREFERRED EMBODIMENTS

Hereinafter, preferred embodiments of a magnetic resonance imaging apparatus according to the present invention will be described with reference to the accompanying drawings. In the accompanying drawings, in some cases, a part of components is not shown for convenience of description.

### First Embodiment

### Configuration of Magnetic Resonance Imaging Apparatus

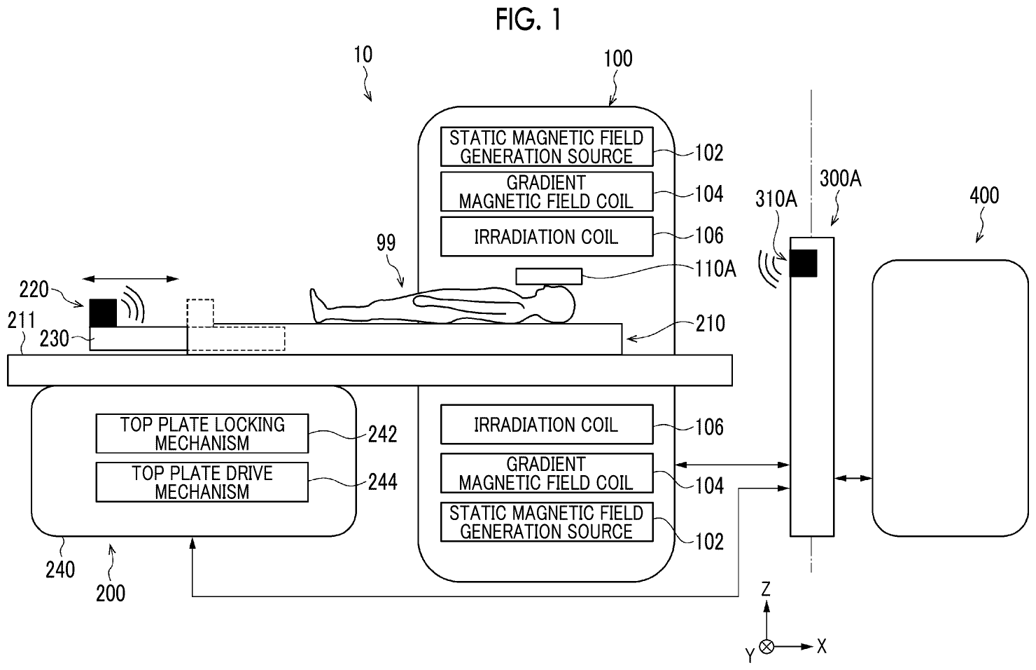

First, an overall configuration of a magnetic resonance imaging apparatus system will be described. FIG. 1 is a schematic diagram showing an overall configuration of a magnetic resonance imaging apparatus 10 (magnetic resonance imaging apparatus, MRI apparatus) according to a first embodiment. As shown in FIG. 1, the magnetic resonance imaging apparatus 10 comprises an imaging apparatus main body 100, a bed device 200, a filter box 300A, and a control device 400 (controller). The magnetic resonance imaging apparatus 10 comprises a power supply and the like (not shown) in addition to these elements. In addition, among components of the magnetic resonance imaging apparatus 10, the imaging apparatus main body 100 and the bed device 200 are installed in a location (examination room, imaging room, or the like) that is radio wave-shielded (and magnetic field-shielded as necessary), and the control device 400 is installed in a location other than the examination room or the like and performs communication via the filter box 300A.

### Imaging Apparatus Main Body

The imaging apparatus main body 100 comprises a static magnetic field generation source 102, a gradient magnetic field coil 104, and an irradiation coil 106. The imaging apparatus main body 100 may be a bore-type apparatus having a tunnel-shaped or cylindrical-shaped imaging space, or may be an open-type apparatus having an open imaging space. The static magnetic field generation source 102 is a coil for generating a uniform static magnetic field in a static magnetic field space in which a subject 99 (subject) is accommodated, and the gradient magnetic field coil 104 is a coil for generating a gradient magnetic field in a superimposed manner in the static magnetic field space. The static magnetic field generation source 102 may be configured of a superconducting magnet (superconducting coil) or may be configured of a normal conductive magnet. The irradiation coil 106 is a coil for irradiating the subject 99 with an RF pulse in order to cause nuclear magnetic resonance to occur in nuclear spins of atoms constituting a biological tissue of the subject 99.

A receive coil 110A (RF coil, receive coil) is configured as, for example, a unit comprising a plurality of receive coil elements (element coils) that are formed in a loop shape and that are disposed in a two-dimensional array, and receives a signal from the subject 99. An image of the subject 99 is captured (reconstructed) based on the signal received by the receive coil 110A. In the magnetic resonance imaging apparatus 10, as the receive coil 110A, a coil for imaging various parts such as a head, a spine, an abdomen, a leg, and an arm can be used. The number of coils used in one imaging may be one or plural, and a plurality of coils (for example, a coil for a chest and a coil for abdomen) for imaging different parts may be used simultaneously. In the first embodiment and second and third embodiments described below, the receive coils with different imaging parts are described as receive coils 110A to 110E, but in the following description, these may be collectively referred to as a “receive coil 110”.

In the first embodiment and the second embodiment described below, the receive coil 110 and a first wireless transceiver such as a wireless transceiver 220A are connected by a cable (wired) (not shown) via a connector 214, but as described in the third embodiment described below, the receive coil 110 and the wireless transceiver 220 may be connected wirelessly.

The bed device 200 comprises a bed main body 240, and a top plate receiver 211 is fixed to the bed main body 240. The top plate receiver 211 holds the top plate 210 (top plate). The bed main body 240 comprises a top plate drive mechanism 244, and the top plate drive mechanism 244 slides the top plate 210 in a longitudinal direction (+X direction in FIG. 1). As the top plate drive mechanism 244, a mechanism such as a rack and pinion, a roller, a wire, or a belt can be used. By sliding the top plate 210, the imaging part of the subject 99 can be moved into the imaging space or the subject 99 can be retracted outside the imaging space.

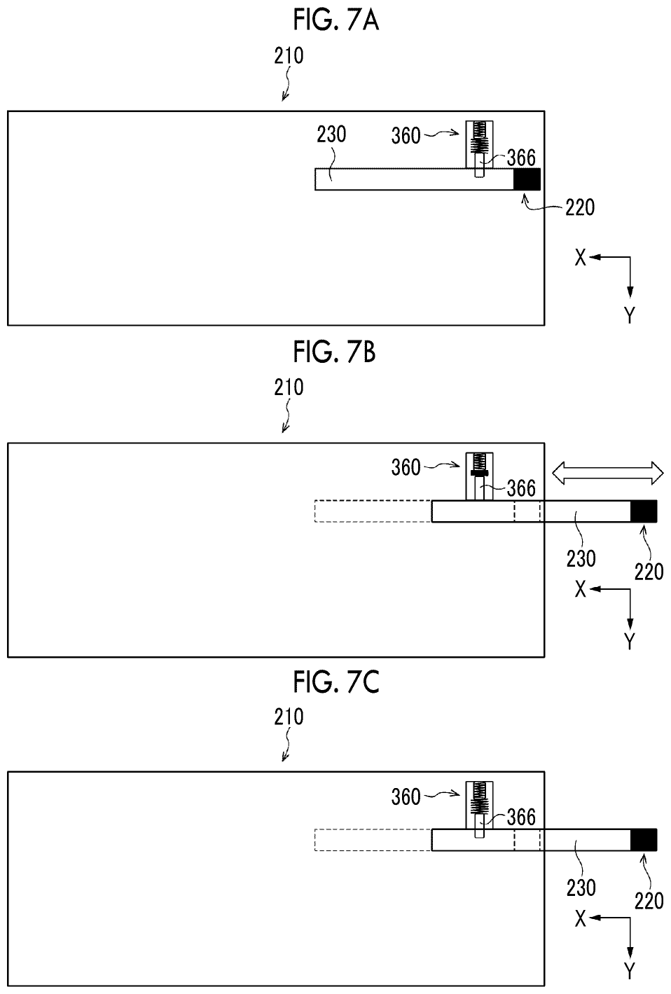

A top plate locking mechanism 242 locks the top plate 210 to prevent it from sliding or unlocks the top plate 210 to allow it to slide. As the top plate locking mechanism 242, similarly to a locking mechanism 360 (see FIGS. 6A and 6B and FIGS. 7A to 7C) of an extension mechanism 230, a mechanism can be adopted in which a locking pin is connected to a solenoid coil via a spring, and the locking pin is retracted or protruded by contracting or expanding the spring by turning on/off energization to the solenoid coil. In addition, a “mechanism in which a magnetic body on the top plate 210 side is attracted or released by turning on/off energization to an electromagnet provided in the top plate receiver 211” may be adopted.

The bed device 200 is connected to the control device 400 via the filter box 300A and is operated under the control of the control device 400.

### Wireless Transceiver (First Wireless Transceiver)

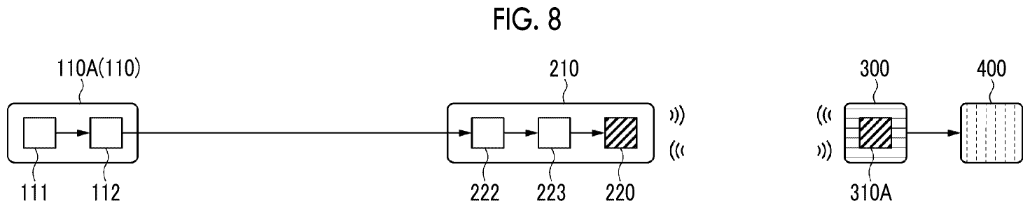

In FIG. 1, the extension mechanism 230 (moving mechanism, extension mechanism) is provided at an end part on the −X side of the top plate 210, and the extension mechanism 230 comprises the wireless transceiver 220 (first wireless transceiver). The extension mechanism 230 moves in the longitudinal direction (+X direction) as the top plate 210 slides, and the wireless transceiver also moves in the longitudinal direction with the sliding. Further, the extension mechanism 230 can be extended from a state of being housed in the top plate 210, and this extension moves the wireless transceiver 220 in a direction (−X side) away from the end part on the −X side of the top plate 210. In a case in which imaging is completed, it is also possible to house the extension mechanism 230 in the top plate 210 as before. The extension mechanism 230 and the wireless transceiver 220 may be provided at the end part on the +X side unlike the disposition in FIG. 1 and the like, or may be provided at both end parts (+X side and −X side) in the longitudinal direction as will be described below for the second embodiment. An AD converter or an optical converter is connected to the wireless transceiver 220 (see description of FIG. 8 described below).

### Disposition of Wireless Transceiver

FIG. 2 is a diagram showing an installation example of the wireless transceiver 220 (first wireless transceiver) in the first embodiment. As shown in FIG. 2, the wireless transceiver 220 is disposed at the end part on the −X side of the top plate 210. In the example of FIG. 2, the wireless transceiver 220 is installed at an end part on the +Y side of the top plate 210, but the position in the Y direction may be an end part on the −Y side or may be in the center or near the center.

In FIG. 2, an opening 213 is provided in the top plate 210, and a connector 214 slides the opening 213 by a sliding mechanism (not shown). The positions, numbers, and sizes of the openings and the connectors may be different from those in the example of FIG. 2. In addition, the position of the connector 214 may be fixed. In a case in which the receive coil 110 and the wireless transceiver 220 are connected in a wired manner, a cable of the receive coil 110 can be connected to the connectors 214. The connector 214 is connected to the wireless transceiver 220 by a cable (not shown).

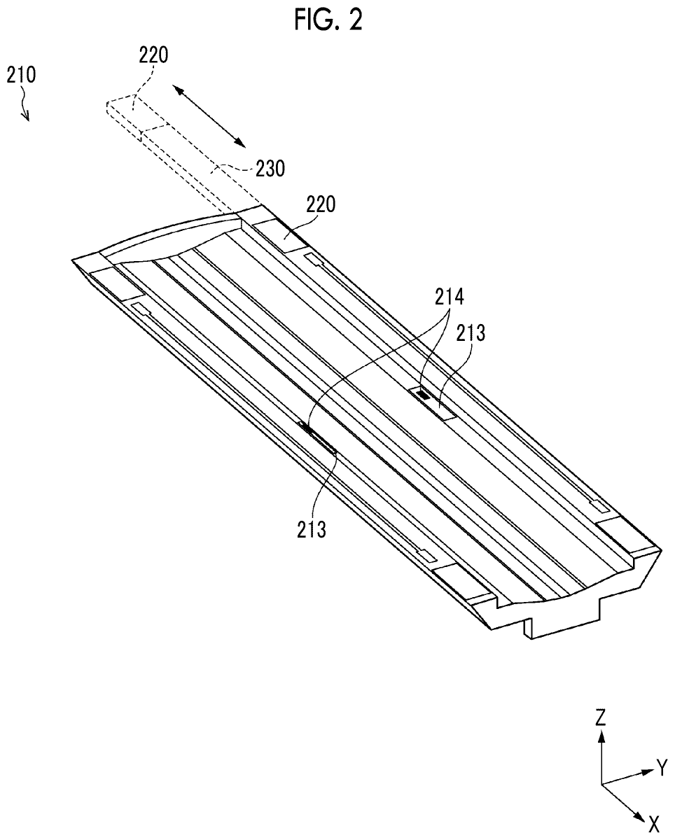

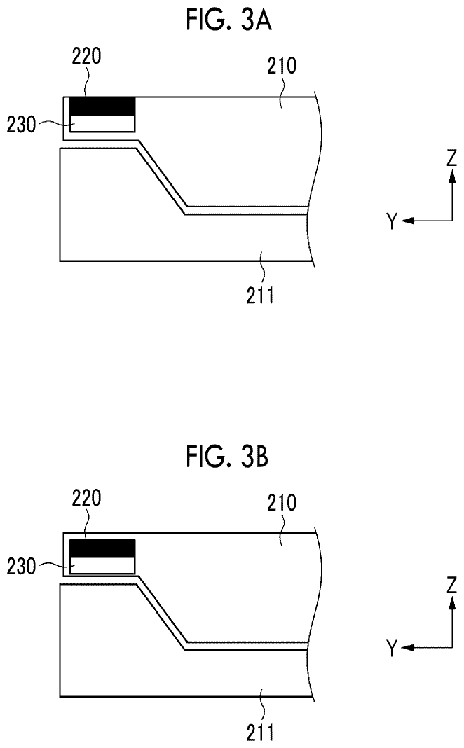

In the example of FIG. 1 described above, for convenience, the wireless transceiver 220 is described as protruding vertically upward (+Z direction) from the top plate 210, but, in consideration of the possibility of an interference with various devices or cables or contact with the subject 99, it is preferable that the wireless transceiver 220 does not protrude from the top plate 210 in the vertical direction. FIGS. 3A and 3B are diagrams showing an installation example (housed state) of the wireless transceiver 220 and the extension mechanism 230. In the example shown in FIG. 3A, an upper surface of the wireless transceiver 220 is flush with an upper surface of the top plate 210, and in the example shown in FIG. 3B, the wireless transceiver 220 is present inside the top plate 210.

### Filter Box

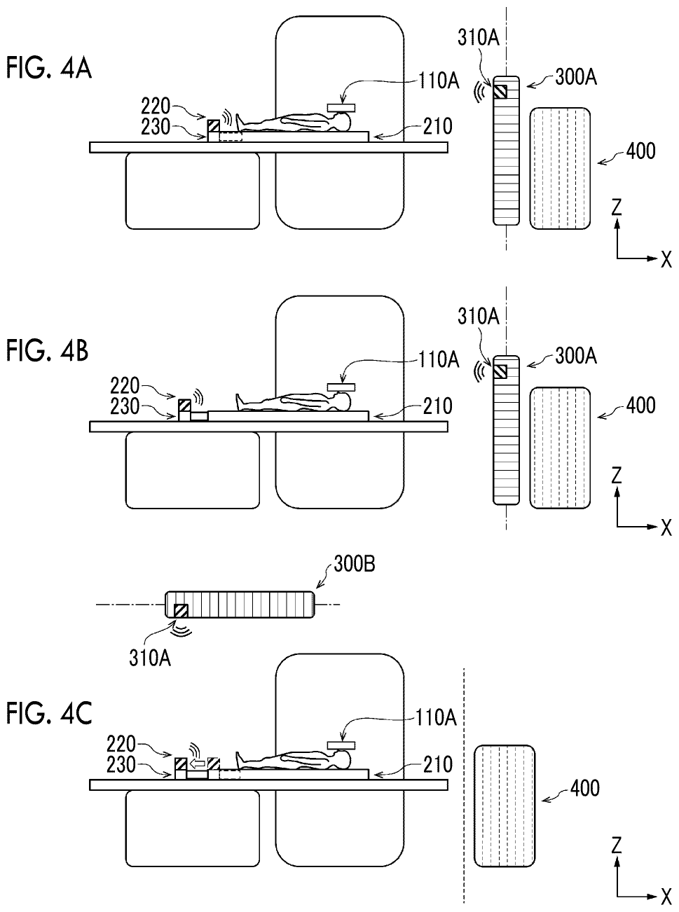

The filter box 300A is provided between an examination room or the like in which the imaging apparatus main body 100 and the bed device 200 are installed and the control device 400, and cables connected to the imaging apparatus main body 100 and the bed device 200 are connected to the control device 400 via the filter box 300A. The filter box 300A and the control device 400 may be connected in a wired manner or in a wireless manner. In the accompanying drawings, filter boxes with different installation positions are described as filter boxes 300A and 300B (FIGS. 4A to 4C and the like), but these may be collectively referred to as a “filter box 300”.

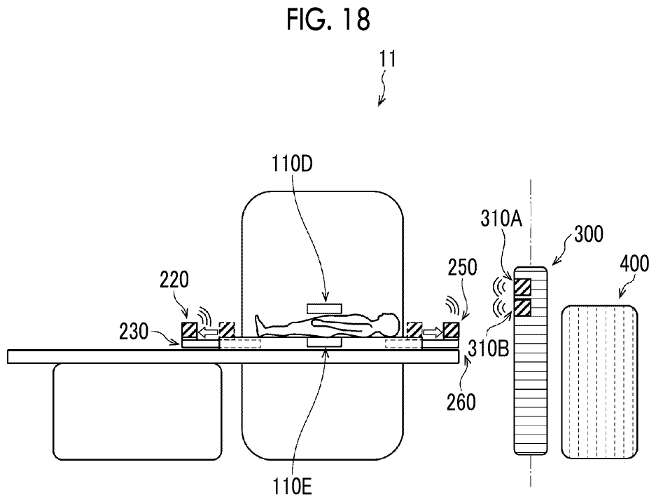

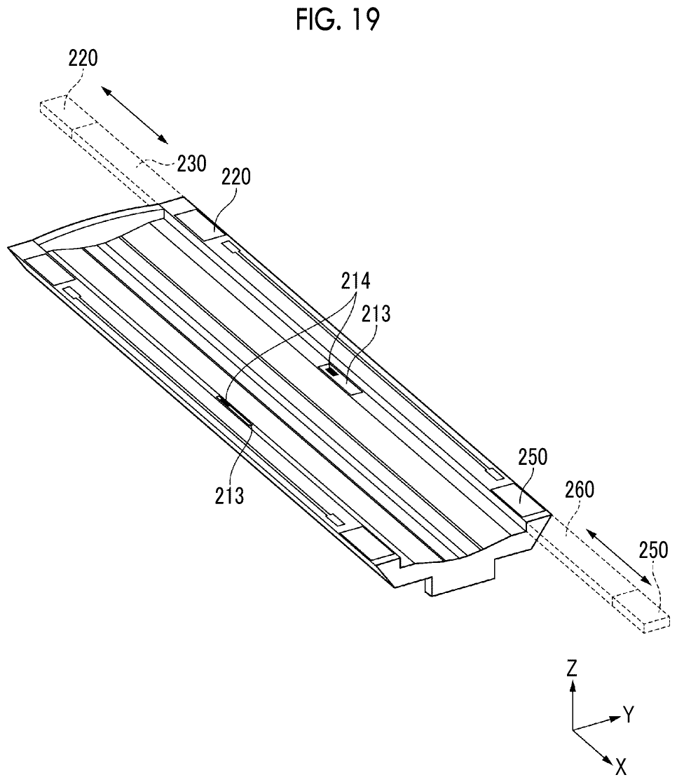

A wireless transceiver 310A (second wireless transceiver) is provided in the filter box 300A, and the control device 400 performs wireless communication using the wireless transceiver 220 and the wireless transceiver 310A. Although the wireless transceivers 310A and 310B are described in the accompanying drawings (FIGS. 1 and 18 and the like), these may be collectively referred to as a “wireless transceiver 310”. In a case of wireless communication using light, the wireless transceiver 310 comprises an optical converter that performs conversion (EO conversion and OE conversion) between an optical signal and an electrical signal.

FIGS. 4A to 4C are diagrams showing a disposition example of the filter box 300 and the wireless transceiver 310. FIGS. 4A and 4B show a state in which the filter box 300A is installed on a wall portion of the examination room. FIG. 4A shows a state in which the extension mechanism 230 is housed in the top plate 210, and FIG. 4B shows a state in which the extension mechanism 230 is extended and the wireless transceiver 220 is moved in the direction (−X direction) away from the end part on the −X side of the top plate 210. In addition, FIG. 4C shows a state in which the filter box 300B is provided on the ceiling portion of the examination room. The extension mechanism 230 is in a state of being extended to the −X side as in FIG. 4B. FIGS. 4A to 4C show a state in which wireless communication is performed between the wireless transceiver 220 and the wireless transceiver 310A.

### Configuration of Extension Mechanism

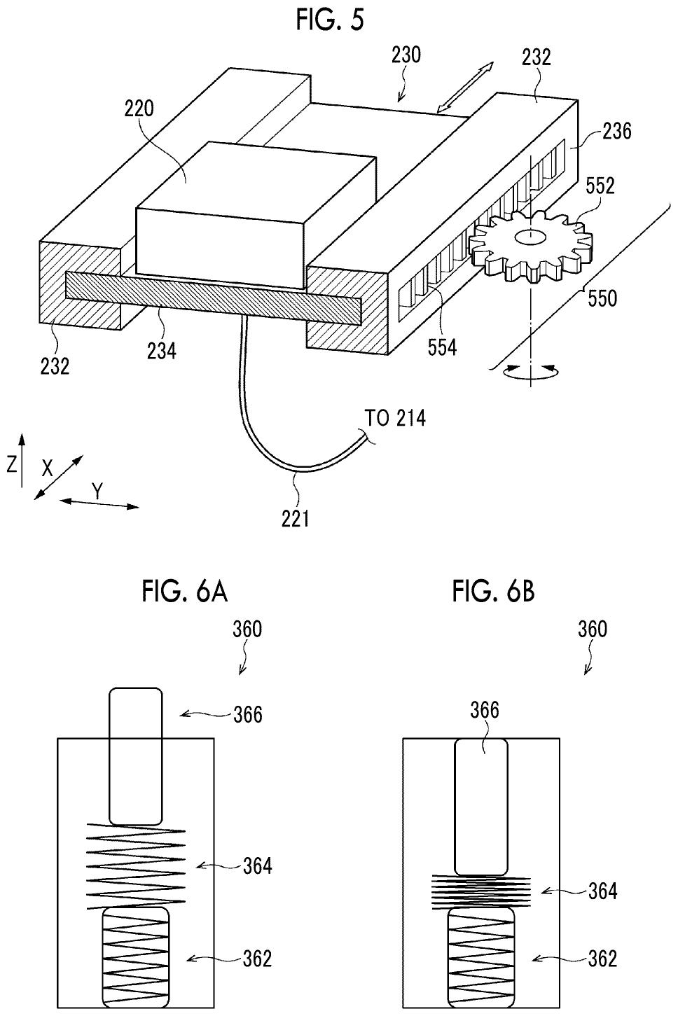

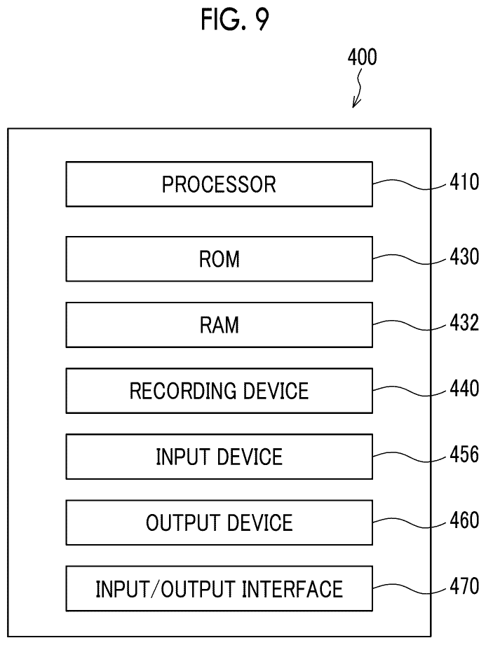

FIG. 5 is a schematic diagram showing a configuration example of the extension mechanism 230 (extension mechanism, moving mechanism). In the example shown in FIG. 5, the wireless transceiver 220 is installed on a flat plate-shaped support member 234, and both end parts of the support member 234 are held by a pair of holding members 232. In addition, the holding member 232 (one in the Y direction) is provided with an opening 236, and a rack 554 is exposed from the opening 236. The rack 554 is fixed to the support member 234. A pinion 552 and the rack 554 constitute a drive mechanism 550. Accordingly, a processor 410 (see FIG. 9) can rotate the pinion 552 (or a gear or the like linked to the pinion 552) using a motor or the like (not shown) to move the rack 554 in parallel, thereby moving the wireless transceiver 220 via the support member 234 (moving in the direction away from the end part of the top plate 210 or returning to the top plate 210 side).

### Locking Mechanism of Extension Mechanism

FIGS. 6A and 6B are diagrams showing a configuration example of the locking mechanism 360 that locks the extension of the extension mechanism 230. As shown in FIGS. 6A and 6B, the locking mechanism 360 comprises a solenoid coil 362, a spring 364 compressed by energization to the solenoid coil 362, and a locking pin 366 connected to the spring 364. It is preferable that the locking mechanism 360 is provided at the end part or near the end part of the top plate 210 to make it difficult for the locking mechanism 360 to enter a magnetic field of the magnetic resonance imaging apparatus 10.

During a period in which the magnetic resonance imaging apparatus 10 is not used or during imaging (a period in which it is necessary to lock the extension of the extension mechanism 230), as shown in FIG. 6A, the energization to the solenoid coil 362 is turned off, the compression of the spring 364 is stopped, and the locking pin 366 protrudes and is inserted into the extension mechanism 230. In a case in which the extension mechanism 230 is extended, the processor 410 energizes the solenoid coil 362, and accordingly, the spring 364 is compressed and the locking pin 366 is attracted as shown in FIG. 6B, so that the extension mechanism 230 can be extended.

### Extending and Housing of Extension Mechanism

FIGS. 7A to 7C are diagrams showing a state of locking/unlocking of the extension mechanism 230 via the above-described locking mechanism 360. FIG. 7A shows a state in which the extension mechanism 230 is housed in the top plate 210 and locked, and the locking mechanism 360 is in a state shown in FIG. 6A. The processor 410 energizes the solenoid coil 362 to bring the locking mechanism 360 into a state shown in FIG. 6B, so that the extension mechanism 230 is unlocked and can be extended as shown in FIG. 7B. In a case in which the extension is ended, the processor 410 stops the energization to the solenoid coil 362, and thus the locking mechanism 360 is brought into the state shown in FIG. 6A again and the extension mechanism 230 is locked. In a case in which the imaging is ended and the extension mechanism 230 is housed in the top plate 210, the above-described procedure need only be performed in reverse. It is preferable that the extension mechanism 230 is provided with a plurality of holes, apertures, grooves, or the like corresponding to the locking pin 366 at a plurality of positions.

The processor 410 may lock the extension mechanism 230 by using a member (not shown) that prevents or releases the rotation of the pinion 552 at any angle.

In the first embodiment, the wireless transceiver 220 (first wireless transceiver) can be moved in multiple stages or continuously by the above-described extension mechanism 230. The same applies to modification examples and second and third embodiments described below.

### Content and Method of Wireless Communication

In the magnetic resonance imaging apparatus 10, various control signals are transmitted from the control device 400 to the wireless transceiver 220 via the wireless transceiver 310, and an image signal and a device operation status are transmitted from the wireless transceiver 220 to the control device 400 via the wireless transceiver 310 (bidirectional communication; see FIG. 8 and related description). The wireless communication may be performed by radio waves or light. That is, the wireless transceiver 220 and the wireless transceiver 310 may be devices that perform wireless communication using radio waves or devices that perform wireless communication using light.

The wireless communication using light can be performed by visible light, infrared rays, or ultraviolet rays, and a signal is transmitted by turning on/off a light-emitting diode (LED), a laser light source, or the like. The communication using light has advantages such as higher speed communication than wireless communication using general radio waves, and no influence on a living body or a peripheral device like radio waves. For wireless communication using visible light (visible light communication (VLC)), a technique called “light fidelity (Li-Fi)” has been proposed, and a standard is defined in IEEE802.11, 802.15.7, and the like.

### State of Wireless Communication

FIG. 8 is a conceptual diagram showing a state of the wireless communication in the first embodiment. As shown in FIG. 8, the receive coil 110A (receive coil 110; RF coil unit) comprises a plurality of element coils 111 and an amplifier 112, and is connected to the top plate 210 by a cable (not shown) (and the connector 214 shown in FIG. 2). A signal from the receive coil 110A (receive coil 110) acquired via the cable is converted into a digital optical signal by an analog-to-digital (AD) converter 222 and an optical converter 223, and is transmitted by the wireless transceiver 220. Since the wireless communication is bidirectionally performed, the wireless transceiver 220 transmits and receives an optical signal, and the optical converter 223 performs EO conversion (conversion from an electrical signal to an optical signal) and OE conversion (conversion from an optical signal to an electrical signal). In a case of wireless communication using radio waves, the optical converter 223 is not necessary. The signal transmitted from the wireless transceiver 220 is received by the wireless transceiver 310 provided in the filter box 300 and is input to the control device 400 (input/output interface 470, processor 410; see FIG. 9). The control signal from the control device 400 is transmitted through a path opposite to the above-described path.

### Control Device

FIG. 9 is a diagram showing a configuration of the control device 400. The control device 400 includes the processor 410, a read only memory (ROM) 430, a random access memory (RAM) 432, a recording device 440, an input device 450, an output device 460, and the input/output interface 470.

### Processor

The processor 410 has, as main functions, an extension control function, a wireless transceiver control function, a bed control function, an imaging control function, a wireless communication control function, and an input/output control function. The processing by these functions will be described in detail below. The processor 410 may have other functions.

The processor 410 is configured of, for example, various processors and electric circuits, such as a central processing unit (CPU), a graphics processing unit (GPU), a field programmable gate array (FPGA), and a programmable logic device (PLD). The functions of the processor 410 do not necessarily correspond one-to-one to the processors and electric circuits. A plurality of functions may be realized by one processor or the like, or one function may be realized by a plurality of processors or the like. In a case in which these processors and electric circuits execute software (program), codes readable by a computer in the software to be executed are recorded on a non-transitory and tangible recording medium such as the ROM 430, and the computer refers to the software. This term “computer” refers to, for example, various processors or electric circuits constituting the processor, and/or a combination thereof.

The software recorded on the non-transitory and tangible recording medium includes a program for acquiring an image signal of a magnetic resonance image, reconstructing the magnetic resonance image, and performing various types of image processing, and data used in executing the program. The code may be recorded on a non-transitory and tangible recording medium, such as a flash ROM or an electronically erasable and programmable read only memory (EEPROM), instead of the ROM 430. The above-described “non-transitory and tangible recording medium” does not include a non-tangible recording medium such as a carrier wave signal or a propagation signal itself. In a case of processing using software, the RAM 432 is used as a transitory storage region or a work region.

### Recording Device

The recording device 440 is composed of a recording medium (non-transitory and tangible recording medium) such as a hard disk, a semiconductor memory, and various magneto-optical recording media, and a controller thereof, and records or stores various types of information. The information recorded on the recording device 440 is, for example, data acquired by the magnetic resonance imaging apparatus 10, a magnetic resonance image (tomographic image or three-dimensional image) obtained by reconstructing the data, an image obtained by performing various types of image processing on the magnetic resonance image, accessory information of the magnetic resonance image, findings or reports for the magnetic resonance image, plans and results of imaging or examination, information indicating an operation status of the wireless transceiver 220 or the wireless transceiver 310, information indicating the selected wireless transceiver, information indicating a movement amount or a movement direction of the wireless transceiver, and information indicating the quality of wireless communication, but is not limited to these examples.

### Input Device

The input device 450 includes a device such as a keyboard or a mouse, and the user can perform an operation necessary for the processing of the magnetic resonance imaging apparatus 10 via these devices. The input device 450 may comprise a microphone (not shown) for voice input. In this case, it is assumed that the processor 410 has a voice recognition function.

### Output Device

The output device 460 (output device) includes a display device such as a liquid crystal display, and can display data recorded on the recording device 440 and a processing result thereof (including a reconstructed image), information indicating an operation status of the wireless transceiver 220 or the wireless transceiver 310, information indicating the selected wireless transceiver, information indicating the quality of wireless communication, information input by the user, and the like. A touch panel type display may be used as the display device and the input device 450. Information (for example, a message to the user) may be output using a speaker (not shown). In addition, the output device 460 may comprise a printer that prints out the above information.

### Movement of Wireless Transceiver due to Extension of Extension Mechanism

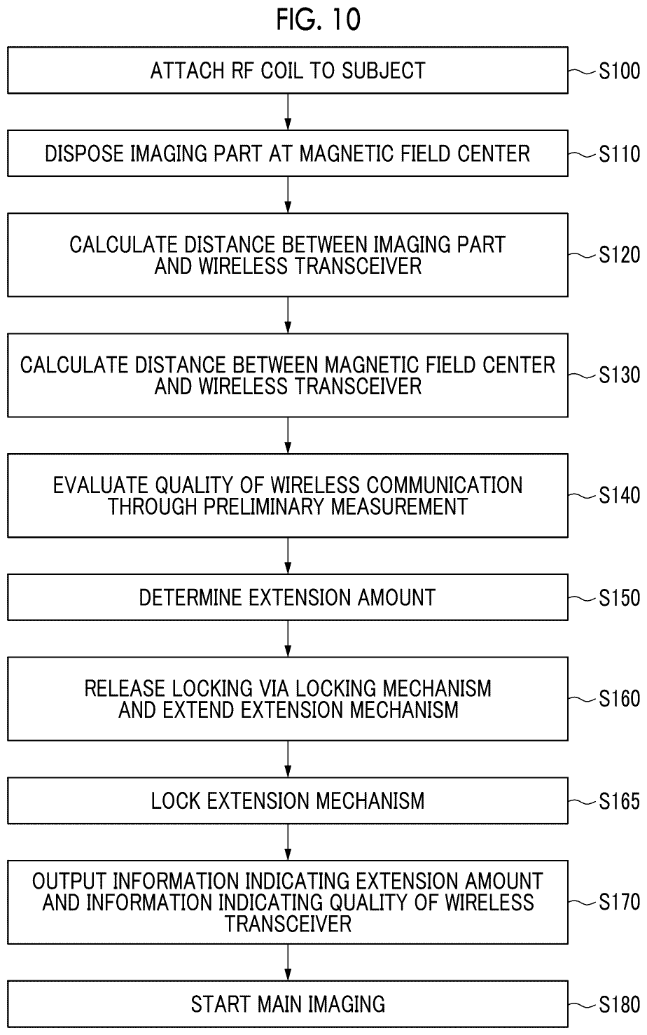

FIG. 10 is a flowchart showing processing (up to start of main imaging) of moving the wireless transceiver 220 (first wireless transceiver) through the extension of the extension mechanism 230.

A user such as a technician attaches the receive coil 110 (RF coil; coil) to the imaging part of the subject 99 in accordance with an examination plan or an imaging condition (step S100). Subsequent processing is performed by the magnetic resonance imaging apparatus 10.

The processor 410 (control device 400; controller) slides the top plate 210 in the +X direction via the top plate drive mechanism 244 to dispose the imaging part at the magnetic field center (center of the imaging space) (step S110). In this case, as will be described in detail below, a positional relationship between the top plate 210 and the imaging space or the magnetic field center varies depending on the imaging part or a body position of the subject 99 (the placement direction on the top plate 210; which of the head and the leg is placed on the +X side), and thus, the movement amount of the wireless transceiver 220 (first wireless transceiver) varies. The processor 410 unlocks the top plate 210 via the top plate locking mechanism 242 before the top plate 210 slides, and locks the top plate 210 again after the sliding is completed.

Steps S120 to S140 are processes for determining the movement amount of the wireless transceiver 220. All of these processes do not have to be performed, and any one or two processes may be performed to determine the movement amount (at least one of the processes in steps S120 to S140 need only be performed). In addition, in a case in which a plurality of processes are performed, the order of the processes does not have to be the order shown in FIG. 10. Which process is to be performed may be determined according to a user operation via the input device 450, or the processor 410 (control device 400) may automatically perform a predetermined process without depending on the user operation. In a case in which a plurality of processes are performed, the result of which process is to be given priority in determining the movement amount may be determined in accordance with the user operation, or the processor 410 (control device 400) may make the determination without depending on the user operation.

The processor 410 (control device 400) calculates a distance between the imaging part and the wireless transceiver 220 (step S120). This distance can be calculated based on information such as the imaging part, the body position of the subject 99, the size of the top plate 210, the installation positions of the wireless transceiver 220, the position of the receive coil 110A (receive coil 110), and the type of coil to be used. In a case in which a plurality of wireless transceivers are provided as in the second embodiment described below, the processor 410 may select the wireless transceiver in consideration of the distance. As described above, the connector 214 is slidable within a range of the opening 213, and the processor 410 can shorten the length of the necessary cable and facilitate the routing by sliding the connector 214.

The processor 410 calculates a distance between the magnetic field center (center of the imaging space) and the wireless transceivers 220A and 220B (step S130). This distance can be calculated based on the imaging part, the body position of the subject 99, the size of the top plate 210, the installation positions of the wireless transceivers 220A and 220B, and the like. In a case in which a plurality of wireless transceivers are provided as in the second embodiment described below, the processor 410 may select the wireless transceiver in consideration of the distance. It is preferable that this distance is long in consideration of the influence of the magnetic field on the wireless communication, and, in a case in which a plurality of wireless transceiver are provided, it is preferable that the processor 410 selects a wireless transceiver outside the imaging space.

The processor 410 may calculate a relationship between an extension amount of the extension mechanism (the movement amount of the wireless transceiver) and the quality of the wireless communication based on the information described above for steps S120 and S130 or the distance calculated in these steps, using a predetermined relational expression, simulation, or the like.

The processor 410 obtains the quality of the wireless communication through preliminary measurement (step S140). The term “preliminary measurement” means, for example, measurement (actual measurement) for the purpose of checking the operation of the MRI apparatus or checking image quality. The quality of the wireless communication is, for example, an intensity of light (an intensity of radio waves in a case of wireless communication using radio waves), an SN ratio, or stability thereof. It is preferable that the preliminary measurement is performed by actual measurement before the main imaging is performed. In a case in which the quality of the wireless communication is low, the processor 410 may output a warning indicating that the quality of the wireless communication is low or a message prompting to change the body position of the subject 99 to the output device 460 (display on a display device, turning on or off warning light, or the like, voice output from a speaker, or the like).

In a case in which the extension mechanism 230 is capable of performing multi-stage or continuous extension, a relationship between the extension amount of the extension mechanism (movement amount of the wireless transceiver) and the quality of the wireless communication may be actually measured for a plurality of extension amounts. In addition, the processor 410 may actually measure the quality for one or more specific extension amounts (for example, the maximum extension amount), and calculate the quality for other extension amounts using a predetermined relational expression, simulation, or the like based on the actual measurement result.

The processor 410 (control device 400) determines the extension amount (the movement amount of the wireless transceiver 220) based on the results of steps S120 to S140 (step S150). The maximum extension amount is not necessarily optimal, and the processor 410 may determine an extension distance less than the maximum extension amount.

In a case in which the optimal extension amount is determined, the processor 410 unlocks the extension mechanism 230 via the locking mechanism 360, extends the extension mechanism 230 by the determined extension amount (step S160: movement by the movement amount determined in step S150), and locks the extension mechanism 230 in a case in which the extension is completed (step S165). In addition, the processor 410 causes the output device 460 to output information indicating the determined extension amount (movement amount) and/or information indicating the position of the wireless transceiver 220 corresponding to the extension amount (step S170). The processor 410 can output the movement amount or the position using a character, a number, a symbol, a figure, or the like.

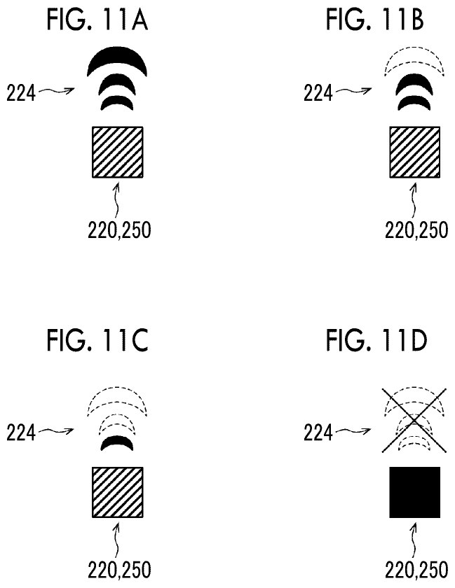

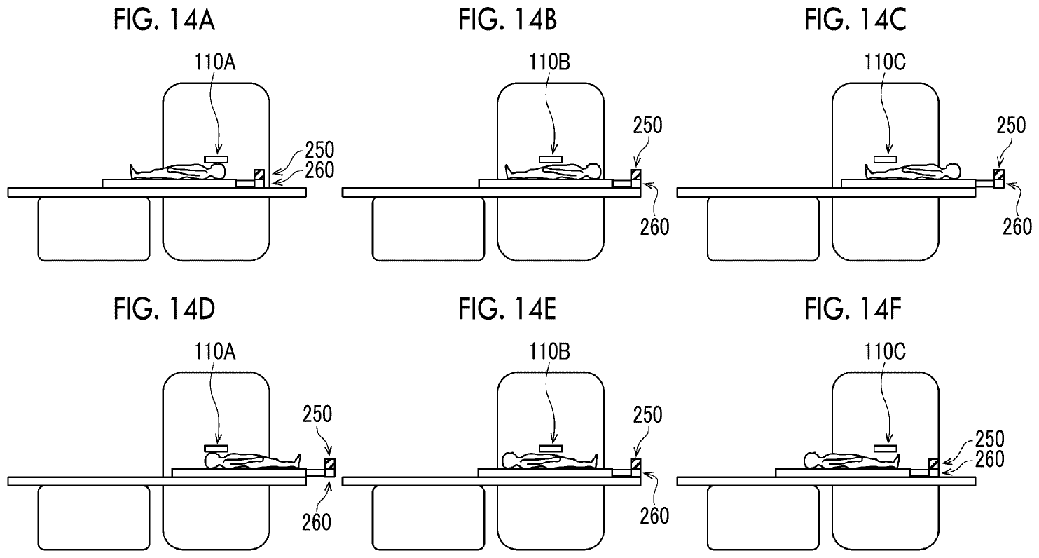

The processor 410 may cause the output device 460 to output information indicating the quality of the wireless communication at the above-described extension amount. For example, the information can be displayed on a display or the like of the output device 460. FIGS. 11A to 11D are diagrams showing an example of quality display of the wireless communication, and the quality is indicated by the number of arc-shaped FIG. 224. As the number of the FIG. 224 increases, the quality is higher (the quality is higher in the order of FIG. 11A to FIG. 11C), and, in a case in which the communication is disconnected, the processor 410 fills the portion of the wireless transceiver as in FIG. 11D, and adds a cross mark to the FIG. 224. FIGS. 11A to 11D show that the same display can be performed for a wireless transceiver 250 (see FIGS. 14A to 14F) in a modification example of the disposition of the wireless transceiver 220 and the extension mechanism 230 described above.

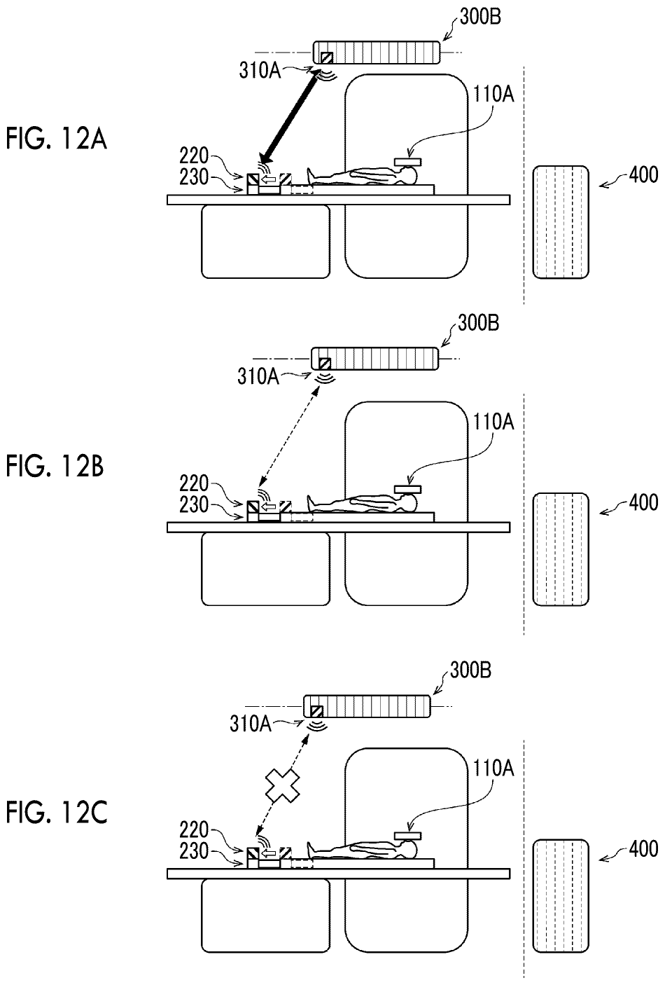

FIGS. 12A to 12C are diagrams showing another example of the quality display of the wireless communication. In FIGS. 12A to 12C, an example of a case in which the filter box 300B is installed on the ceiling is shown. FIG. 12A shows that the quality of the wireless communication between the wireless transceiver 220 and the wireless transceiver 310A is high, in which a thickness of an arrow connecting the wireless transceiver 220 and the wireless transceiver 310A represents a quality level. FIG. 12B shows a state in which the quality of the wireless communication is lower than that in the case of FIG. 12A, and this state is represented by a thin dotted line. FIG. 12C shows a state in which the wireless communication is disconnected, and this state is indicated by a cross mark. The quality of the wireless communication may be displayed by color, a number, a graph, or the like, or may be output by voice from the speaker of the output device 460. Similarly, the extension amount may also be displayed by color, a number, a graph, an animation (for example, in the diagrams showing the magnetic resonance imaging apparatus 10 such as FIG. 1 and FIGS. 12A to 12C, the positions of the extension mechanism 230 and the wireless transceiver 220 are changed depending on the housed state or the extension distance), or the like, or may be output by voice from the speaker of the output device 460. In the display shown in FIGS. 12A to 12C, it is preferable to display both the extension amount and the quality.

With the output shown in FIGS. 11A to 11D and FIGS. 12A to 12C, the user can easily know the extension amount and the quality of the wireless communication.

After locking the extension mechanism 230 in step S165, the processor 410 starts the main imaging (step S180). The main imaging may be started before or after the output of step S170. The term “main imaging” means, for example, an act of capturing a magnetic resonance image used for examination or diagnosis of the subject.

According to the first embodiment, by the extension of the extension mechanism 230 and the movement of the wireless transceiver 220, it is possible to perform high-quality wireless communication and acquire the magnetic resonance image.

The processor 410 (controller) may measure the quality of the wireless communication again after the wireless transceiver 220 (first wireless transceiver) is moved, determine the movement amount again according to a result of the re-measurement, and move the wireless transceiver 220 (first wireless transceiver) by the movement amount determined again.

### Imaging in Consideration of Imaging Part and Body Position

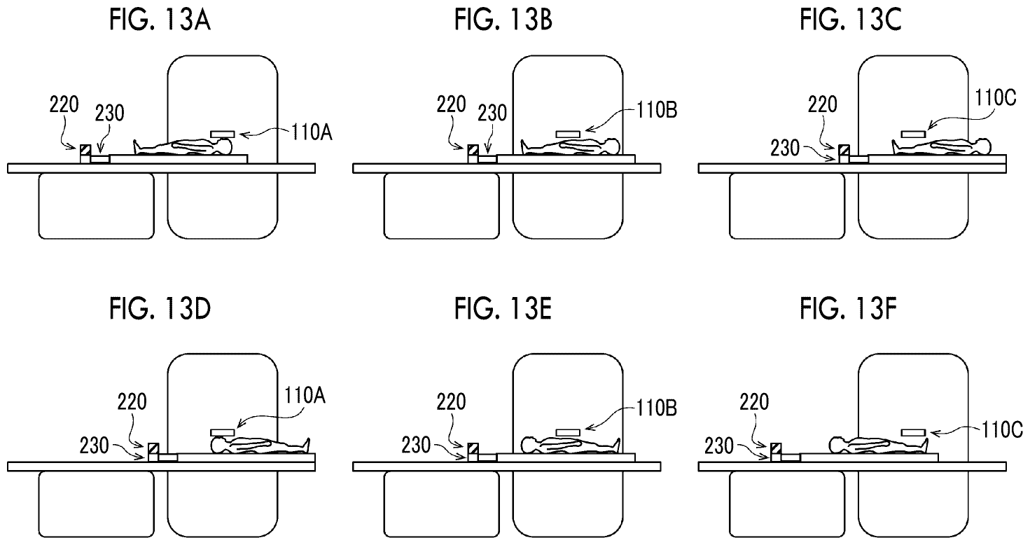

FIGS. 13A to 13F are diagrams showing an aspect of imaging in consideration of the imaging part and the body position (the placement direction of the subject 99 on the top plate 210). FIGS. 13A to 13C show a state of imaging in “Head First” (in a case in which the subject is transported to the imaging space with the head first), and FIGS. 13D to 13F show a state of imaging in “Foot First” (in a case in which the subject is transported to the imaging space with the foot first). In addition, FIG. 13A and FIG. 13D show a state in which the head is imaged, FIG. 13B and FIG. 13E show a state in which the abdomen is imaged, and FIG. 13C and FIG. 13F show a state in which the leg is imaged. In the imaging of the head, the abdomen, and the leg, the receive coils 110A, 110B, and 110C (coils) are used, respectively.

In a case in which the extension mechanism 230 is not provided, the wireless transceiver 220 enters the imaging space in the case shown in FIG. 13C. However, according to the first embodiment, even in such a case, the extension mechanism 230 can be extended to move the wireless transceiver 220, thereby moving the wireless transceiver 220 outside the imaging space to reduce the influence of the magnetic field or the like on the wireless communication. In addition, according to the first embodiment, in other cases as well, the extension mechanism 230 can be extended to move the wireless transceiver 220, thereby moving the wireless transceiver 220 away from the magnetic field center and reducing the influence of the magnetic field or the like on the wireless communication.

### Modification Example

A modification example of the above-described first embodiment will be described.

### Modification Example of Disposition of Extension Mechanism and Wireless Transceiver

In the magnetic resonance imaging apparatus 10 according to the first embodiment, the extension mechanism 230 and the wireless transceiver 220 are provided at the end part on the −X side of the top plate 210, but in a magnetic resonance imaging apparatus of the modification example of the present invention, an extension mechanism 260 and a wireless transceiver 250 may be provided at the end part on +X side of the top plate 210.

FIGS. 14A to 14F are diagrams showing a modification example of the disposition of the extension mechanism and the wireless transceiver, and a relationship between the imaging part and the body position in the modification example. FIGS. 14A to 14C show an aspect of imaging in “Head First”, and FIGS. 14D to 14F show an aspect of imaging in “Foot First”. In addition, FIG. 14A and FIG. 14D show a state in which the head is imaged, FIG. 14B and FIG. 14E show a state in which the abdomen is imaged, and FIG. 14C and FIG. 14F show a state in which the leg is imaged. In the imaging of the head, the abdomen, and the leg, the receive coils 110A, 110B, and 110C (coils) are used, respectively.

In a case in which the extension mechanism 260 is not provided, the wireless transceiver 250 may enter the imaging space or may be close to the imaging space (or the magnetic field center). However, according to the modification example, even in such a case, the extension mechanism 260 can be extended to move the wireless transceiver 250 to the +X side (in the direction away from the end part on the +X side of the top plate 210), thereby moving the wireless transceiver 250 outside the imaging space to reduce the influence of the magnetic field or the like on the wireless communication. In addition, according to the modification example, in other cases as well, the extension mechanism 260 can be extended to move the wireless transceiver 250, thereby moving the wireless transceiver 250 away from the imaging space or the magnetic field center and reducing the influence of the static magnetic field or the like on the wireless communication.

In the example of FIGS. 14A to 14F, in the cases shown in FIGS. 14A and 14F, the wireless transceiver 250 enters the imaging space, but in this case, such a state can be resolved by changing the body position of the subject 99 (Head First or Foot First). In these cases in which the wireless transceiver enters the imaging space or is close to the magnetic field center, or in which the quality of the wireless communication is low due to these reasons, it is preferable that the processor 410 outputs the quality of the wireless communication to warn the user about this issue as described above with reference to FIGS. 11A to 11D and FIGS. 12A to 12C, or causes the output device 460 to output a message prompting the user to change the body position of the subject 99.

### Modification Example of Extension Mechanism (Part 1)

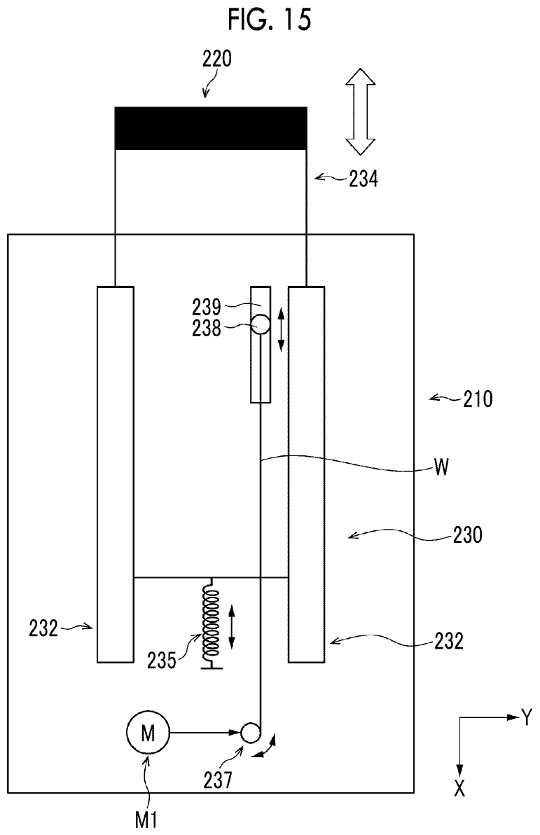

In the example of FIG. 5, a case in which the drive mechanism 550 is configured by the pinion 552 and the rack 554 has been described, but the drive of the extension mechanism is not limited to such an aspect. For example, a configuration as in a modification example (part 1) shown in the schematic diagram of FIG. 15 may be adopted. In the modification example shown in FIG. 15, a spring 235 is provided, one end of the spring 235 is fixed to the end part on the +X side of the support member 234, the other end is fixed to the top plate 210, and the extension of the extension mechanism 230 is locked in a state where the spring 235 is compressed in a case in which the extension mechanism 230 is housed. The spring 235 does not have to be a coil spring, and the number of the springs 235 is not limited to one and may be plural. Another biasing member may be used. In a case in which the processor 410 unlocks the extension mechanism 230, the compressed spring 235 is released, and the extension mechanism 230 can be extended by a biasing force.

In addition, a rotary shaft 237 is provided on the top plate 210, and a wire W is wound around the rotary shaft 237. Further, the support member 234 is provided with a pin 238 (the position of which is fixed). The pin 238 is slidable in a groove 239 (which may be an opening) provided in the longitudinal direction (±X direction) of the top plate 210. In a case in which the extension mechanism 230 is housed in the top plate 210, the pin 238 slides in the +X direction and the spring 235 is compressed by winding the wire W around the rotary shaft 237 by a motor M1. In a case in which the wireless transceiver 220 is housed in the top plate 210, the processor 410 locks the slide of the extension mechanism 230 (support member 234).

In a case in which the extension mechanism 230 is unlocked, it is preferable to control the processor 410 and the motor M1 to gradually release the winding of the wire W around the rotary shaft 237 in order to prevent the wireless transceiver 220 from suddenly protruding. In addition, a plurality of the wires W, rotary shafts 237, pins 238, and grooves 239 may be provided.

### Modification Example of Extension Mechanism (Part 2)

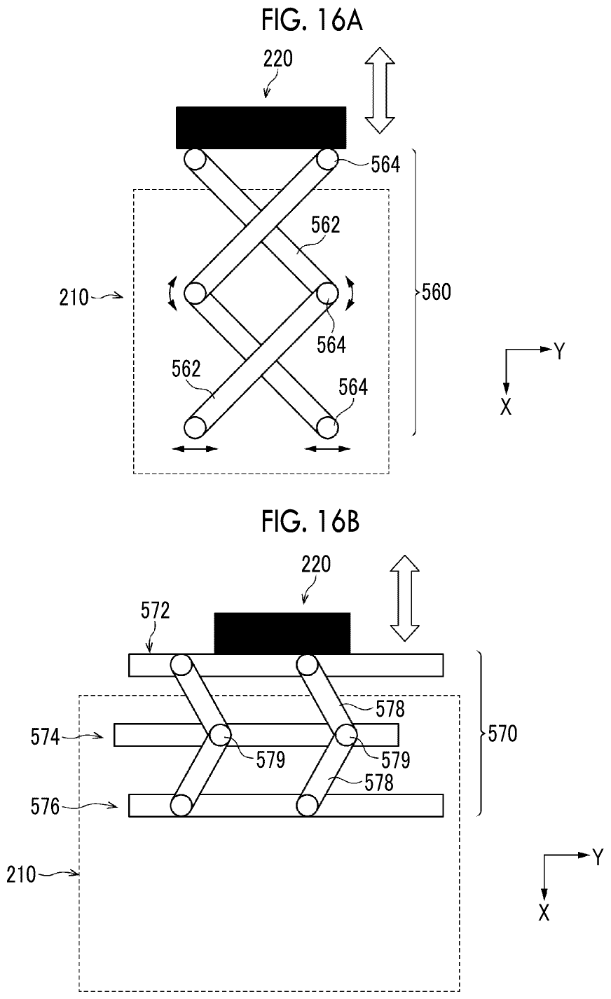

FIGS. 16A and 16B are schematic diagrams showing a modification example (part 2) of the extension mechanism. An extension mechanism 560 (extension mechanism, moving mechanism) shown in FIG. 16A is composed of a plurality of arm members 562 disposed crosswise and pins 564 provided at end parts of the arm members 562. A position of the pin 564 closest to the +X side is fixed in the +X direction with respect to the top plate 210. In this state, for example, by sliding the pin 564 on the +X side to the left and right in the drawing (in the +Y direction) or rotating the pin 564 in an intermediate portion, the extension mechanism 560 can be extended or retracted in the +X direction as a whole, thereby moving the wireless transceiver 220 in the direction away from the end part on the −X side of the top plate 210 or conversely, housing the wireless transceiver 220 in the top plate 210.

An extension mechanism 570 (extension mechanism, moving mechanism) shown in FIG. 16B is composed of plate-shaped members 572, 574, and 576 disposed in parallel, and arm members 578 and pins 579 that connect the plate-shaped members. The plate-shaped member 576 is fixed to the top plate 210, and the wireless transceiver 220 is installed on the plate-shaped member 572. In this state, the extension mechanism 570 is extended or retracted by pushing or pulling the arm member 578 and/or the plate-shaped members 572 and 574 (a configuration as shown in FIG. 15 can be adopted) or rotating the pin 579, thereby moving the wireless transceiver 220 in the direction away from the end part on the −X side of the top plate 210 (the plate-shaped members 572, 574, and 576 are extended or retracted in the +X direction while maintaining the parallel state), or conversely, housing the wireless transceiver 220 in the top plate 210.

### Modification Example of Moving Mechanism

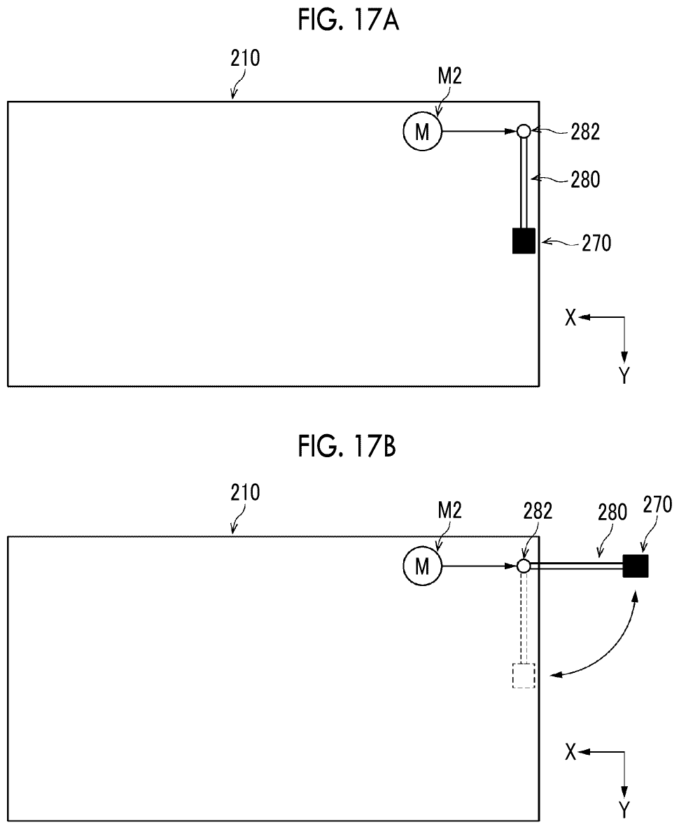

In the first embodiment and the modification example described above, a case in which the moving mechanism is the extension mechanism has been described, but the moving mechanism for moving the wireless transceiver in the direction away from the end part of the top plate 210 is not limited to the extension mechanism that extends linearly from the end part. For example, as shown in schematic diagrams of FIGS. 17A and 17B, a shaft member 282 (rotary shaft) and an arm member 280 may be provided at the end part of the top plate 210, and a wireless transceiver 270 may be installed at a tip of the arm member 280. Then, by rotating the shaft member 282 and the arm member 280 using a motor M2, a state in which the wireless transceiver 270 is housed in the top plate 210 (FIG. 17A) and a state in which the wireless transceiver 270 is away from the end part on the −X side of the top plate 210 (FIG. 17B) can be realized. In addition, even in the moving mechanism having such a configuration, it is preferable to provide a locking mechanism for restricting the rotation of the arm member 280 and the shaft member 282 and the movement of the wireless transceiver 270.

As described above, according to the first embodiment and the modification example thereof, it is possible to perform high-quality wireless communication and capture the magnetic resonance image while reducing or avoiding the influence of the static magnetic field or the like.

### Second Embodiment

In the first embodiment and the modification example described above, a case in which the moving mechanism is provided at one end part of the top plate 210 in the longitudinal direction has been described, but the moving mechanism may be provided at both end parts of the top plate 210. For example, as shown in FIG. 18 (a diagram showing a main configuration of a magnetic resonance imaging apparatus according to the second embodiment) and FIG. 19 (a diagram showing an installation example of a wireless transceiver in the second embodiment), in a magnetic resonance imaging apparatus 11, the wireless transceiver 220 may be installed by providing the extension mechanism 230 (extension mechanism, moving mechanism) at the end part on the −X side of the top plate 210, and the wireless transceiver 250 may be installed by providing the extension mechanism 260 (extension mechanism, moving mechanism) at the end part on the +X side. In this case, either extension mechanism can move the wireless transceiver in the direction away from the end part of the top plate 210. In addition, in the example of FIG. 19, the wireless transceiver is disposed on the +Y side of the top plate 210, but the wireless transceiver may be disposed on the −Y side. Further, in the examples of FIGS. 18 and 19, one wireless transceiver is disposed at each end part in the +X direction (longitudinal direction), but a plurality of wireless transceivers may be disposed at one end part or at both end parts. For example, a total of four wireless transceivers may be disposed, two at each end part in the +X directions.

The same modification examples (see FIG. 15 to FIGS. 17A and 17B) as those described for the first embodiment may be adopted for the extension mechanisms 230 and 260. In addition, in the second embodiment, the same configurations as those in the first embodiment can be adopted for configurations other than the above-described configurations.

With the magnetic resonance imaging apparatus 11 having such a configuration, it is possible to increase a degree of freedom of selection for the wireless transceiver used for the wireless communication or the movement of the wireless transceiver, and it is possible to cope with a case in which the wireless transceiver enters the imaging space or is close to the magnetic field center in the configuration of the first embodiment, and to reduce or avoid the influence of the static magnetic field or the like, and to capture the magnetic resonance image through high-quality wireless communication. In the second embodiment, in a case of wide area imaging (chest and abdomen or the like), imaging may be performed using the wireless transceivers 220 and 250 (first wireless transceivers) at both ends. In addition, in response to this, it is preferable that a plurality of the wireless transceivers 310A and 310B (second wireless transceivers) are also provided in the filter box 300. The filter box 300 may be disposed on the ceiling as in the first embodiment (see the examples in FIGS. 4A to 4C).

### Configuration of Control Device

The configuration of the control device is basically the same as that of the first embodiment (see FIG. 9), but in the second embodiment, the processor 410 further performs “selection of whether to perform the wireless communication using which of the wireless transceivers 220 and 250 or to perform the wireless communication using both the wireless transceivers 220 and 250” and “calculation of the extension amount for each wireless transceiver”.

### State of Wireless Communication

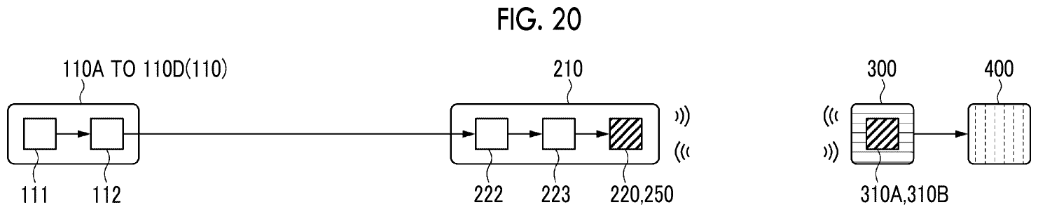

FIG. 20 is a diagram showing a state of the wireless communication in the second embodiment. In the second embodiment, the wireless communication can be performed in the same manner as in the first embodiment using the wireless transceivers 220 and 250 (first wireless transceivers) and the wireless transceivers 310A and 310B (second wireless transceivers).

### Selection of Wireless Transceiver and Movement of Wireless Transceiver

In the second embodiment, the processor 410 can also perform the imaging by extending the extension mechanisms 230 and 260 (extension mechanism, moving mechanism) as in the case of the first embodiment (see the flowchart of FIG. 10). In addition, the processor 410 can perform one or more of processes of steps S120 to S140 in the flowchart of FIG. 10 for each of the wireless transceivers 220 and 250, and can determine the wireless transceiver to be moved and the extension amount (movement amount) based on the result. The processor 410 may set a priority order for a plurality of wireless transceivers (the wireless transceivers 220 and 250) in a case of selecting or determining the wireless transceiver to be moved, and may perform the switching of the wireless transceivers according to the priority order in a case in which the wireless communication is disconnected or the quality of the wireless communication is deteriorated. It is preferable that the processor 410 sets the priority order by prioritizing the quality of the wireless communication.

In addition, the processor 410 may determine the extension amount (movement amount) in consideration of one or more of the imaging part of the subject 99, the placement direction of the subject on the top plate 210, and the size of the imaging space of the magnetic resonance imaging apparatus 10, or may determine the extension amount (movement amount) for positioning the wireless transceivers 220 and 250 outside the imaging space.

Relationship between Interval between Wireless Transceivers and Size of Imaging Space

In the second embodiment, a length of the top plate 210 in the longitudinal direction (±X direction) is, for example, 2,500 mm, and a size of the imaging space (here, for convenience, a length of the imaging apparatus main body 100 in the +X direction) is, for example, 2,000 mm. In addition, it is assumed that the wireless transceivers 220 and 250 are installed at both end parts in the longitudinal direction and can be further extended. In this case, an interval between the installation positions of the wireless transceivers 220 and 250 in the longitudinal direction is longer than a length of the imaging space of the magnetic resonance imaging apparatus 11 in the longitudinal direction, and the wireless transceivers 220 and 250 are installed at both end parts of the top plate 210 and can be further extended, so that at least one of the wireless transceiver 220 or the wireless transceiver 250 is located outside the imaging space in a state in which the subject 99 is imaged. The processor 410 can consider such a relationship in a case of selecting the wireless transceiver (first wireless transceiver) (for example, instead of or in addition to the determination in steps S120 to S140 described above), and can reduce or avoid the influence of the static magnetic field or the like and perform high-quality (signal intensity, SN ratio, stability, and the like) wireless communication to capture the magnetic resonance image by selecting the wireless transceiver located outside the imaging space. The length of the top plate 210 and the size of the imaging space described above are examples, and the length and the size may be different from the above. For example, the size of the imaging space may be about 1,800 mm or may be about 2,400 mm.

It is preferable that the processor 410 does not operate a wireless transceiver that is not used for the wireless communication (including power off). In addition, it is preferable that the processor 410 causes the output device 460 to output information indicating the determined extension amount (movement amount) and/or information indicating the position of the wireless transceiver 220 corresponding to the extension amount, and it is preferable that the processor 410 causes the output device 460 to output information indicating the quality of the wireless communication (see FIGS. 11A to 11D and FIGS. 12A to 12C).

Case in which Wireless Communication Is Disconnected or Quality of Wireless Communication Is Deteriorated

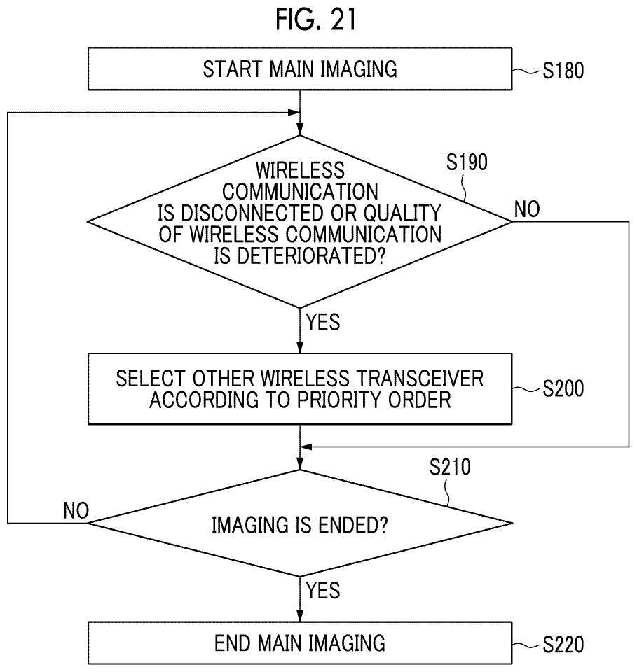

Since the magnetic resonance imaging apparatus 10 according to the second embodiment comprises the plurality of wireless transceivers 220 and 250 (first wireless transceivers), the wireless transceiver can be switched in a case in which the wireless communication of one wireless transceiver is disconnected or the quality of the wireless communication is deteriorated. FIG. 21 is a flowchart showing processing in a case in which the wireless communication is disconnected or the quality of the wireless communication is deteriorated. In a case in which the wireless communication is disconnected or the quality of the wireless communication is deteriorated (YES in step S190), the processor 410 selects a wireless transceiver other than the wireless transceiver selected in step S150 (step S200) and continues the wireless communication. For example, in a case in which the wireless communication is disconnected or the quality of the wireless communication is deteriorated while the wireless transceiver 220 is selected, the processor 410 selects the wireless transceiver 250, which is a “wireless transceiver other than the wireless transceiver 220”, and continues the wireless communication.

### Third Embodiment

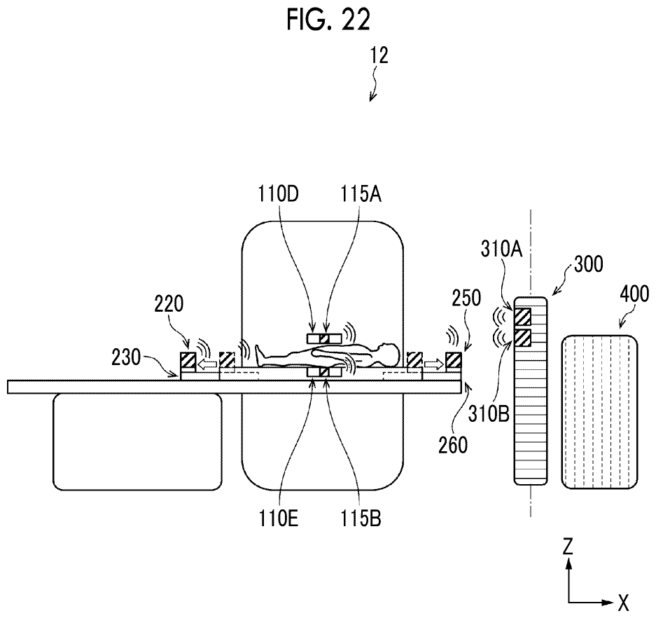

In the first and second embodiments described above, the receive coil 110 (coil) and the wireless transceivers 220 and 250 (first wireless transceiver) are connected by a cable, but the receive coil 110 and the first wireless transceiver may be connected wirelessly. Specifically, as shown in FIG. 22 (a diagram showing a main configuration of a magnetic resonance imaging apparatus according to the third embodiment), in a magnetic resonance imaging apparatus 12, wireless transceivers 115A and 115B (third wireless transceivers) may be provided in receive coils 110D and 110E (coils), and wireless communication may be performed with the wireless transceivers 220 and 250 (first wireless transceivers). As a result, in addition to the same effects as those of the first and second embodiments (reducing or avoiding the influence of the static magnetic field or the like and acquiring the magnetic resonance image by performing high-quality wireless communication), it is possible to reduce the number of cables and connectors and to reduce the probability of interference or contact between the cables or the connectors and other devices, and the influence on the subject.

In the third embodiment, the same configurations as those in the first and second embodiments can be adopted for configurations other than the above-described configurations.

In the third embodiment, wireless communication can also be performed between the wireless transceivers 220 and 250 and the wireless transceivers 310A and 310B (second wireless transceivers) in the same manner as in the first and second embodiments. In addition, the wireless transceivers 220 and 250 (first wireless transceivers) are included in the aspect of FIG. 22, but the selection of these wireless transceivers can be performed in the same manner as in the second embodiment. In addition, even in a case in which the wireless communication is disconnected or the quality of the wireless communication is deteriorated, it is possible to cope with this issue as in the second embodiment.

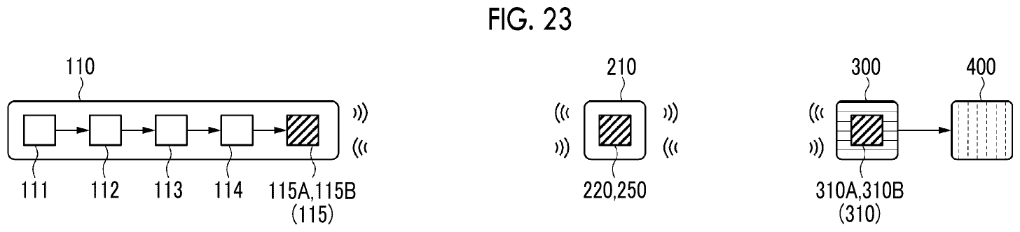

FIG. 23 is a diagram showing a state of the wireless communication in the third embodiment. As shown in FIG. 23, signals received by the receive coils 110D and 110E (receive coils 110; RF coil units) are converted into digital optical signals by a plurality of element coils 111, an amplifier 112, an AD converter 113, and an optical converter 114, and are transmitted by the wireless transceivers 115A and 115B (third wireless transceivers). Since the wireless communication is bidirectionally performed, the wireless transceivers 115A and 115B transmit and receive optical signals, and the optical converter 114 performs EO conversion and OE conversion. In a case of wireless communication using radio waves, the optical converter 114 is not necessary. The signals transmitted from the wireless transceivers 115A and 115B are received by the wireless transceivers 310A and 310B (wireless transceivers 310: second wireless transceivers) provided in the filter box 300 via the wireless transceivers 220 and 250 (first wireless transceivers), and are input to the control device 400 (input/output interface 470, processor 410; see FIG. 9). The control signal from the control device 400 is transmitted through a path opposite to the above-described path.

In the third embodiment, the same configurations as those of the first and second embodiments or the modification examples can be adopted for the extension mechanism (moving mechanism) of the wireless transceivers 220 and 250 (first wireless transceivers).

### Others

The present invention is not limited to the above-described embodiments and modification examples, and various modifications can be made.

### EXPLANATION OF REFERENCES

10: magnetic resonance imaging apparatus
99: subject
100: imaging apparatus main body
102: static magnetic field generation source
104: gradient magnetic field coil
106: irradiation coil
110A: receive coil
200: bed device
210: top plate
211: top plate receiver
220: wireless transceiver
230: extension mechanism
240: bed main body
242: top plate locking mechanism
244: top plate drive mechanism
300A: filter box
310A: wireless transceiver
400: control device
Steps S100 to S180: each process for selecting wireless transceiver

What is claimed is:

1. A magnetic resonance imaging apparatus comprising:
a top plate on which a subject is placed, the top plate being slidable in a longitudinal direction;
a first wireless transceiver connected to a receive coil for capturing a magnetic resonance image of the subject;
a moving mechanism that moves the first wireless transceiver in a direction away from an end part of the top plate in the longitudinal direction;
a second wireless transceiver; and
a controller that controls movement of the first wireless transceiver via the moving mechanism and wireless communication using the first wireless transceiver and the second wireless transceiver,
wherein the controller determines a movement amount of the first wireless transceiver via the moving mechanism and performs the wireless communication by moving the first wireless transceiver by the determined movement amount via the moving mechanism.

2. The magnetic resonance imaging apparatus according to claim 1,
wherein the controller determines the movement amount in consideration of one or more of an imaging part of the subject, a direction of placing the subject on the top plate, and a size of an imaging space of the magnetic resonance imaging apparatus.

3. The magnetic resonance imaging apparatus according to claim 1,
wherein the controller determines a movement amount for positioning the first wireless transceiver outside an imaging space of the magnetic resonance imaging apparatus, as the movement amount.

4. The magnetic resonance imaging apparatus according to claim 1,
wherein the controller determines the movement amount in consideration of quality of the wireless communication.

5. The magnetic resonance imaging apparatus according to claim 1,
wherein the controller obtains quality of the wireless communication through preliminary measurement before main imaging.

6. The magnetic resonance imaging apparatus according to claim 1,
wherein the controller measures quality of the wireless communication after the first wireless transceiver is moved, determines the movement amount again according to a result of the measurement, and moves the first wireless transceiver by the movement amount determined again.

7. The magnetic resonance imaging apparatus according to claim 1, further comprising:
a locking mechanism that locks and unlocks movement of the first wireless transceiver via the moving mechanism,
wherein the controller unlocks the moving mechanism via the locking mechanism during the movement, and locks the moving mechanism via the locking mechanism after the movement is ended.

8. The magnetic resonance imaging apparatus according to claim 1,
wherein the moving mechanisms are provided at both end parts of the top plate in the longitudinal direction, and
the first wireless transceivers are provided corresponding to the moving mechanisms at both end parts of the top plate.

9. The magnetic resonance imaging apparatus according to claim 8,
wherein the controller selects the first wireless transceiver provided at either one of both end parts of the top plate, and performs the wireless communication using the selected first wireless transceiver.

10. The magnetic resonance imaging apparatus according to claim 1,
wherein the moving mechanism moves the first wireless transceiver in multiple stages or continuously.

11. The magnetic resonance imaging apparatus according to claim 1,
wherein the controller causes an output device to output information indicating the movement amount and/or a position of the first wireless transceiver corresponding to the movement amount.

12. The magnetic resonance imaging apparatus according to claim 1,
wherein the controller causes an output device to output information indicating quality of the wireless communication in a state in which the moving mechanism moves the first wireless transceiver.

13. The magnetic resonance imaging apparatus according to claim 1,
wherein the moving mechanism is an extension mechanism provided on the top plate, and
the controller extends the extension mechanism to move the first wireless transceiver in the direction away from the end part of the top plate in a case of imaging the subject.

14. The magnetic resonance imaging apparatus according to claim 1,
wherein the moving mechanism includes an arm member provided on the top plate, one end part of the arm member serving as a rotary shaft,
the first wireless transceiver is provided at the other end part of the arm member, and
the controller moves the first wireless transceiver in the direction away from the end part of the top plate by rotating the arm member.

15. The magnetic resonance imaging apparatus according to claim 1,
wherein the first wireless transceiver and the receive coil are connected by wireless communication.

16. The magnetic resonance imaging apparatus according to claim 1,
wherein the wireless communication is wireless communication using light.
